(19) United States
(12) Patent Application Publication
(10) Pub. No.: US 2021/0373217 A1
(43) Pub. Date: Dec. 2, 2021

(54) FINE PATTERN FORMING METHOD, IMPRINT MOLD MANUFACTURING METHOD, IMPRINT MOLD, AND OPTICAL DEVICE

(71) Applicant: SCIVAX CORPORATION, Kanagawa (JP)

(72) Inventors: Daiji Tanabe, Kanagawa (JP); Nobuyoshi Awaya, Kanagawa (JP); Satoru Tanaka, Kanagawa (JP)

(21) Appl. No.: 17/285,992

(22) PCT Filed: Oct. 15, 2019
(86) PCT No.: PCT/JP2019/040525

§ 371 Date: Apr. 16, 2021

(30) Foreign Application Priority Data
Oct. 16, 2018 (JP) 2018-195214

(51) Int. Cl. G02B 5/30; B29C 33/38; G03F 7/00

(52) U.S. Cl. CPC G02B 5/30; G03F 7/0002; B29C 33/3842

(57) ABSTRACT

A forming method of forming a micropattern which has a direction and a position controlled for each predetermined position on an object subjected to pattern formation, and an imprinting mold producing method, an imprinting mold and an optical device to which such a forming method is applied. A first mask pattern forming process of forming, by imprinting, a first mask pattern for forming the micropattern on a surface of an object subjected to pattern formation, the surface including a region where at least the micropattern is not formed yet; a second mask pattern forming process of forming a resist film on the object subjected to pattern formation and on the first mask pattern, exposing and developing such a film by light emission to form a second mask pattern that causes a region where the micropattern is not formed but the first mask patten is formed to appear in an uncovered manner; and a micropattern forming process of performing etching on the object subjected to pattern formation to form the micropattern. The first mask pattern forming process, the second mask pattern forming process and the micropattern forming process are repeated in this sequence.

### TECHNICAL FIELD

The present disclosure relates to a micropattern forming method, an imprinting mold producing method, an imprinting mold and an optical device.

### BACKGROUND ART

Optical members are utilized which have a microscopic concavo-convex structure formed on a surface for controlling optical characteristics, such as a lens for concentration of light, a moss eye for antireflection, and a wire grid for adjusting polarization of light. As for a method of forming such a microscopic structure, nano-imprinting is getting attention which utilizes a mold (a metal mold) that has the inverted structure of such a microscopic structure formed on a surface, pressurizes such a mold against an object subjected to pattern formation, and transfers the pattern on the surface of such an object by heat or light (see, for example, Patent Document 1).

In this case, regarding a mold utilized for imprinting, first, a master mold is created by laser beam machining. Next, imprinting is directly performed on a resin from the master mold, and thus the mold is created. Moreover, a mold may be also created by electroforming from a master mold, and imprinting may be performed on a resin from the mold having undergone the electroforming, and thus the mold is created.

### CITATION LIST

### Patent Literatures

Patent Document 1: WO 2004/062886

### SUMMARY OF INVENTION

### Technical Problem

In recent years, a demand of a wire grid polarizer with a large area for a liquid crystal display is increasing. However, it is difficult for an exposure device for a liquid crystal large screen to form a pattern that is equal to or smaller than 200-nm pitch required for a wire grid polarizer. Moreover, although a micropattern can be formed by nanoimprinting, the size of a master mold is 300 mm at the maximum, and thus it is necessary to perform imprinting by several times when patterns are formed in a large-area substrate. However, regarding the imprinting, the alignment precision is insufficient, and thus it is difficult to form a seamless pattern.

Moreover, it is desired in some cases to form patterns which have respective directions and positions controlled for predetermined position by predetermined position on a substrate, such as a case in which wire grids that have respective polarization directions different by 90 degrees are formed on respective optical elements like image sensors. Moreover, in the technical field of optical lens, in order to prevent moire, etc., it is desired to forma pattern which has a direction and a position controlled for each predetermined position. In such cases, however, as described above, regarding imprinting, the alignment precision is not sufficient, and thus it is difficult to form a pattern with the direction and the position being controlled.

Hence, an objective of the present disclosure is to provide a forming method capable of forming a micropattern which has a direction and a position controlled for each predetermined position on an object subjected to pattern formation, and an imprinting mold producing method, an imprinting mold and an optical device to which such a forming method is applied.

### Solution to Problem

In order to accomplish the above objective, a forming method of forming a micropattern according to the present disclosure includes:

a first mask pattern forming process of forming, by imprinting, a first mask pattern for forming the micropattern on a surface of an object subjected to pattern formation, the surface including a region where at least the micropattern is not formed yet;

a second mask pattern forming process of forming a resist film on the object subjected to pattern formation and on the first mask pattern, exposing and developing the resist film by light emission to form a second mask pattern that causes a region where the micropattern is not formed but the first mask patten is formed to appear in an uncovered manner.

This method also includes a micropattern forming process of performing etching using the first mask pattern and the second mask pattern to form the micropattern on the object subjected to pattern formation.

The first mask pattern forming process, the second mask pattern forming process and the micropattern forming process are repeated in this sequence to form the micropattern.

In this case, the light emission in the second mask pattern forming process may utilize laser lithography.

The first mask pattern forming process, the second mask pattern forming process and the micropattern forming process are repeated by three times. This enables a formation of the micropatterns within the shortest time without any space between the micropatterns.

It is preferable that the light emission in the second mask pattern forming process subsequent to at least a second time should be performed using an alignment marking formed on the object subjected to pattern formation.

The forming method of the present disclosure may further includes an alignment marking forming process of forming a resist film on the object subjected to pattern formation, exposing and developing the resist film by light emission to form an alignment marking mask pattern, performing etching using the alignment marking mask pattern, and forming the alignment marking on the object subjected to pattern formation. Moreover, the alignment marking forming process may be to expose the resist film formed in the second mask pattern forming process at a first time by light emission, to form the alignment marking mask pattern simultaneously with the formation of the second mask pattern by the development in the second mask pattern forming process at the first time, and to form the alignment marking by the etching in the micropattern forming process at the first time.

It is preferable that the micropattern should have a pitch that is equal to or smaller than 200 nm.

It is preferable that the above-described imprinting should include:

an applying process of causing a mold that has an inverted pattern of the first mask pattern to contact a stamp stage on which a film formed of a resin with a film thickness of equal to or smaller than 200 nm is formed to apply the resin on a surface of the mold; and

a transferring process of depressing the mold against the object subjected to pattern formation, releasing the mold after the resin is cured to form the first mask pattern on the surface of the object subjected to pattern formation.

Furthermore, another forming method according to the present disclosure includes:

a hard mask forming process of forming, on the object subjected to pattern formation and formed on a substrate, a hard mask that includes the first micropattern formed by the forming method according to any one of claims 1 to 8; and

a second micropattern forming process of performing etching using the hard mask to form a second micropattern on the substate. Such a forming method is applicable to, for example, an imprinting mold producing method of forming an imprinting mold.

Still further, an imprinting mold according to the present disclosure includes:

a plurality of micropatterns each in a line-and-space shape and coupled to each other; and

alignment markings provided around regions where the respective micropatterns are formed.

An optical device according to the present disclosure includes:

a plurality of optical elements formed on a substrate; and

plural kinds of wire grids formed on the respective optical elements.

### Advantageous Effects of Invention

The forming method according to the present disclosure can form the micropattern having the direction and the position controlled for each predetermined position on the object subjected to pattern formation. Moreover, application of the forming method according to the present disclosure enables a production of an imprinting mold with a large area, and of an optical device, etc.

### BRIEF DESCRIPTION OF DRAWINGS

FIGS. 1A to I are each a schematic cross-sectional view for describing imprinting;

FIG. 2A is a schematic plan view, and FIGS. 2B to D are schematic cross-sectional views illustrating an object subjected to pattern formation according to the present disclosure;

FIG. 3A is a schematic plan view, and FIGS. 3B to 3D are schematic cross-sectional views illustrating a first mask pattern according to the present disclosure;

FIG. 4A is a schematic plan view, and FIGS. 4B to 4D are schematic cross-sectional views illustrating a resist film according to the present disclosure;

FIG. 5A is a schematic plan view, and FIGS. 5B to 5D are schematic cross-sectional views illustrating a second mask pattern according to the present disclosure;

FIG. 6A is a schematic plan view, and FIGS. 6B to 6D are schematic cross-sectional views illustrating a micropattern forming process according to the present disclosure;

FIG. 7A is a schematic plan view, and FIGS. 7B to 7D are schematic cross-sectional views illustrating a peeling process of a resin and of a resist film according to the present disclosure;

FIG. 8A is a schematic plan view, and FIGS. 8B to 8D are schematic cross-sectional views illustrating the first mask pattern at the second time according to the present disclosure;

FIG. 9A is a schematic plan view, and FIGS. 9B to 9D are schematic cross-sectional views illustrating the second mask pattern at the second time according to the present disclosure;

FIG. 10A is a schematic plan view, and FIGS. 10B to 10D are schematic cross-sectional views illustrating the micropattern forming process at the second time according to the present disclosure;

FIG. 11A is a schematic plan view, and FIGS. 11B to 11D are schematic cross-sectional views illustrating the peeling process of the resin and of the resist film at the second time according to the present disclosure;

FIG. 12A is a schematic plan view, and FIGS. 12B to 12D are schematic cross-sectional views illustrating the first mask pattern at the third time according to the present disclosure;

FIG. 13A is a schematic plan view, and FIGS. 13B to 13D are schematic cross-sectional views illustrating the second mask pattern at the third time according to the present disclosure;

FIG. 14A is a schematic plan view, and FIGS. 14B to 14D are schematic cross-sectional views illustrating the micropattern forming process at the third time according to the present disclosure;

FIG. 15A is a schematic plan view, and FIGS. 15B to 15D are schematic cross-sectional views illustrating the peeling process of the resin and of the resist film at the third time according to the present disclosure;

FIG. 16A is a schematic plan view, and FIGS. 16B to 16D are schematic cross-sectional views illustrating a second micropattern forming process according to the present disclosure;

FIG. 17A is a schematic plan view, and FIGS. 17B to 17D are schematic cross-sectional views illustrating a hard mask peeling process according to the present disclosure;

FIG. 18A is a schematic plan view, and FIGS. 18B to 18D are schematic cross-sectional views illustrating a part of a substrate in which an optical element is formed according to the present disclosure;

FIGS. 19A to 19E are schematic plan views illustrating a first mask pattern forming process, a second mask pattern forming process, and a micropattern forming process at the first time according to the present disclosure;

FIGS. 20A to 20E are schematic plan views illustrating the first mask pattern forming process, the second mask pattern forming process, and the micropattern forming process at the second time according to the present disclosure; and

FIG. 21 is a schematic plan view illustrating an optical device according to the present disclosure.

### DESCRIPTION OF EMBODIMENTS

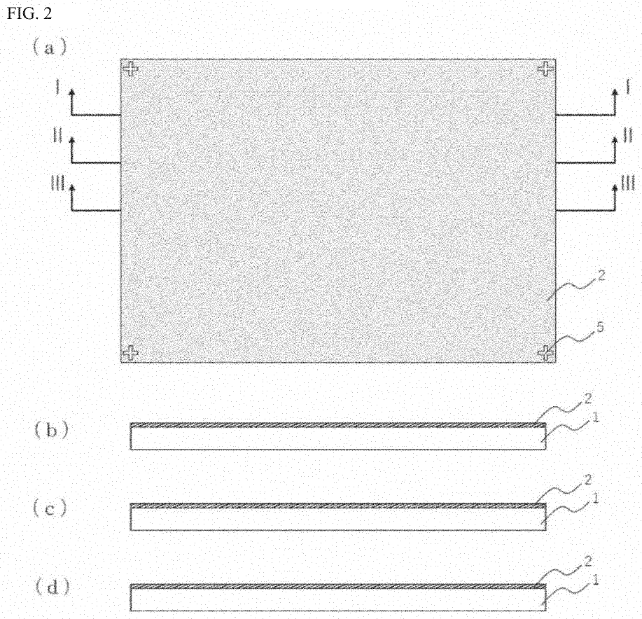

A micropattern forming method according to the present disclosure will be described below with reference to the figures. Note that in FIGS. 2 to 17, respective figures B are cross-sectional views taken along a line I-I in respective figures A, respective figures C are cross-sectional views taken along a line II-II in the respective figures A, and respective figures C are cross-sectional views taken along a line III-III in the respective figures A. The micropattern forming method according to the present disclosure includes a first mask pattern forming process of forming, by imprinting, a first mask pattern 31 to form a micropattern 21 on the surface of an object 2 subjected to pattern formation which includes a region where at least the micropattern 21 is not formed yet, a second mask pattern forming process of forming a resist film 4 on the object 2 subjected to pattern formation and on the first mask pattern 31, exposing and developing the resist film 4 by light emission so as to form a second mask pattern 41 that causes a region where the micropattern 21 is not formed but the first mask pattern 31 is formed to appear in an uncovered manner, and a micropattern forming process of performing etching using the first mask pattern 31 and the second mask pattern 41 so as to form the micropattern 21 on the object 2 subjected to pattern formation. The first mask pattern forming process, the second mask pattern forming process, and the micropattern forming process are repeated in this sequence, thereby forming the micropattern 21.

The first mask pattern forming process is to form the first mask pattern 31 by imprinting on the surface of the object 2 subjected to pattern formation that is advantageous for micropattern formation. The first mask pattern 31 is formed so as to cover a region on the object 2 subjected to pattern formation where at least the micropattern 21 is not formed. Moreover, when a pattern is to be formed on an object subjected to pattern formation with a large area, it is appropriate if the plurality of first mask patterns 31 is arranged on the object 2 subjected to pattern formation to form the large-area pattern.

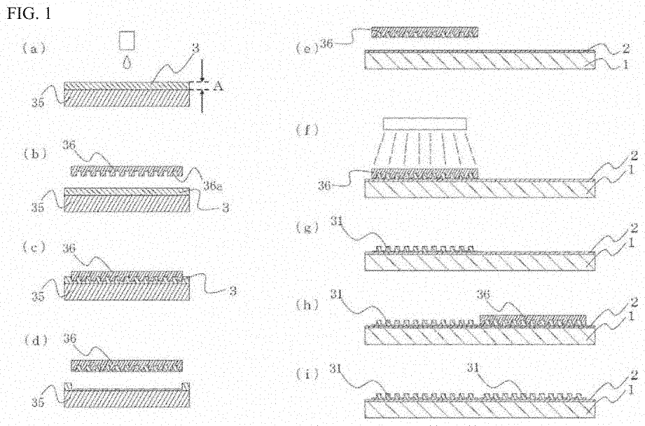

Imprinting will now be described. The imprinting according to the present disclosure is to press a mold 36 that has an inverted pattern 36a of the first mask pattern 31 which is to be formed on a resin, to form the first mask pattern 31 by utilizing heat or light, and to cure the resin, thereby transferring the first mask pattern 31 on the object 2 subjected to pattern formation. There are various imprinting methods, and any imprinting methods are applicable as long as the first mask pattern 31 can be formed on the surface of the object 2 subjected to pattern formation. For example, as for the imprinting method that can reduce the remaining film pieces of the first mask pattern 31, as illustrated in FIGS. 1A to 1I, there is a method that includes an applying process of causing the mold 36 which has the inverted pattern 36a of the first mask pattern 31 to contact a stamp stage 35 on which a resin film 3 formed of a resin with a film thickness of equal to or smaller than 200 nm is formed to apply the resin to the surface of the mold 36, and a transferring process of pressing the mold 36 against the object 2 subjected to pattern formation, and of removing such a die after the resin is cured, thereby forming the first mask pattern 31 on the surface of the object 2 subjected to pattern formation.

Regarding the applying process, first, as illustrated in FIG. 1A, the resin film 3 is formed on the stamp stage 35 in advance. Next, as illustrated in FIGS. 1B and 1C, the mold 36 is caused to contact the resin film 3 on the stamp stage 35. Eventually, as illustrated in FIG. 1D, the mold 36 is removed from the stamp stage 35 to apply the resin to the surface of the mold 36. Note that regarding the resin film 3 on the stamp stage 35, when a film thickness A as illustrated in FIG. 1A is large, since the thickness of the resin (the remaining film piece) in the concavity of the formed first mask pattern 31 becomes large, it is not preferable. Hence, it is preferable that the resin film 3 on the stamp stage 35 should have the film thickness A that is equal to or smaller than 200 nm, more preferably, equal to or smaller than 100 nm, and further preferably, equal to or smaller than 50 nm. The preferable resin film 3 that is formed on the stamp stage 35 has the film thickness A that is equal to or smaller than 200 nm, and conventionally well-known methods, such as spin coating, spray coating, and slit coating, are applicable to form such a resin film.

The mold 36 (the imprinting mold) is formed of, for example, “metal like nickel”, “ceramics”, “silica glass”, “silicon”, and “carbon material like glass-like carbon”, etc., and has, on one end surface (formation surface), the inverted pattern 36a of the first mask pattern 31 to be formed. The inverted pattern 36a can be formed by performing precision machining on the formation surface. Moreover, it can be formed by semiconductor microfabrication technologies like etching on a silicon substrate, etc., or can be formed by performing metal plating on the surface of such a silicon substrate by an electroforming technology (electroforming) like nickel plating, and by peeling this metal plating layer. Furthermore, a mold formed of resin produced by imprinting is also applicable. In this case, the mold 36 may be formed in a film shape that is flexible relative to the surface of the object 2 subjected to pattern formation. Needless to say, the material and producing method of the mold 36 are not limited to any particular ones as long as it can transfer the first mask pattern 31.

Moreover, regarding the inverted pattern 36a, the minimum dimensions, such as the width of the convexity and the width of the concavity in the planar direction, are formed in various dimensions, such as equal to or smaller than 1 μm, equal to or smaller than 100 nm, and equal to or smaller than 10 nm. Moreover, the dimension in the depthwise direction is also formed in various dimensions, such as equal to or greater than 10 nm, equal to or greater than 100 nm, equal to or greater than 200 nm, equal to or greater than 500 nm, and equal to or greater than 1 μm. Note that, in the case of, for example, the pattern necessary for a wire grid polarizer applied to a liquid-crystal display, the pitch of the concavo-convex structure is equal to or greater than 50 nm and equal to or smaller than 200 nm, the width of convexity is equal to or greater than 25 nm and equal to or smaller than 100 nm, and the aspect ratio of the convexity is equal to or greater than 1.

Furthermore, the resin applied for the first mask pattern forming process is not limited to any particular one as long as it can form the first mask pattern 31 by imprinting, and enables etching on the object 2 subjected to pattern formation by utilizing the first mask pattern 31 so as to form the micropattern 21. For example, a photo-curable resin, a thermosetting resin, or a thermoplastic resin is applicable.

Example applicable photo-curable resin or thermosetting resin are unsaturated hydrocarbon radical containing compounds like vinyl group and allylic group, such as epoxide-containing chemical compounds, (metha) acrylic ester compounds, vinyl-ether compounds, and bisallyl nadiimide compounds. In this case, for the purpose of thermal polymerization, polymerization-reactivity-group-containing compounds may be applied individually, and for the purpose of improving the thermosetting characteristics, a thermal reactivity initiator may be added and applied. Furthermore, a photoreactive initiator may be added, and polymerization reaction may be progressed by light emission to form the first mask pattern 31. As for the thermal reactive radical initiator, organic peroxide and azo compound can be applied appropriately, and as for the photoreactive radical initiator, acetophenone derivative, benzophenone derivative, benzoin ether derivative, xanthone derivative, etc., can be applied appropriately. Moreover, reactant monomer can be utilized without a solvent, or may be dissolved in a solvent, and may be subjected to desolvation after applied.

Moreover, example thermoplastic resins applicable are cyclic-olefin-based resin, such as cyclic olefin ring opening polymerization/hydrogen additive (COP), or cyclic olefin copolymer (COC), acrylic resin, polycarbonate, vinyl-ether resin, fluorine resin, such as perfluoroalkoxyalcan (PFA) or polytetrafluoroethylene (PTFE), polystyrene, polyimide-based resin, and polyester-based resin, etc.

As illustrated in FIG. 1C, after the mold 36 is caused to contact the stamp stage 35, and as illustrated in FIG. 1D, when the mold 36 is separated from the stamp stage 35, regarding the resin at an end portion of the mold 36, depending on the condition like the viscosity of the resin, a large amount of resin may be applied, or a little amount of resin may be applied. In such a case, it is preferable to adjust the film thickness of the resin to be applied to the mold 36 by forming the end portion of the stamp stage 35 so as to have a higher or lower height than that of the center portion. Normally, the stamp stage 35 is formed so as to be sufficiently large relative to the mold 36, but in order to adjust the film thickness of the resin to be applied to the mold 36, the stamp stage 35 may be formed so as to have the same planar shape as that of the mold 36.

As illustrated in FIGS. 1E to 1G, the transferring process is to press the mold 36 against the object 2 subjected to pattern formation, and to remove the mold after the resin is cured, thereby forming the first mask pattern 31 on the surface of the object 2 subjected to pattern formation.

In this example, the object 2 subjected to pattern formation is an object which is in a planar shape with a sufficient area that enables formation of the first mask pattern 31, and on which the desired micropattern 21 is to be formed. The object 2 subjected to pattern formation is not limited to any particular one as long as the micropattern 21 can be formed by performing etching on the formed first mask pattern 31, and for example, a resin, an inorganic compound like glass, or metal like chromium, are applicable. Moreover, the object 2 subjected to pattern formation itself may be a substrate or a film, and as illustrated in FIG. 2A, it may be a thin film like a hard mask formed on a substrate 1.

It is appropriate if the mold 36 is pressed against the object 2 subjected to pattern formation in such a way that the resin applied on the surface of the mold 36 can contact the object 2 subjected to pattern formation and can be fastened firmly. The pressure to press the mold 36 against the object 2 subjected to pattern formation is sufficient if it causes the first mask pattern 31 to firmly fastened to the object 2 subjected to pattern formation when the mold is removed, and for example, the mold 36 may be pressed against the object 2 subjected to pattern formation at 0.5 to 2 MPa.

The curing of the resin may be caused by, as illustrated in FIG. 1F, emitting light with a predetermined wavelength that can cure the resin, e.g., ultraviolet ray to the resin when the resin is a photo-curable resin. Note that in FIG. 1F, light is emitted from the mold side, but when the object 2 subjected to pattern formation is a light transmissive material, light may be emitted from the object-2-subjected-to-pattern-formation side.

Moreover, although it is not illustrated, when the resin is a thermosetting resin, the resin may be cured by heating, and when the resin is a thermoplastic resin, the resin may be cured by cooling to a temperature that is equal to or lower than the glass transition temperature.

After the resin is sufficiently cured, as illustrated in FIG. 1G, the mold 36 is removed from the object 2 subjected to pattern formation, thereby forming the first mask pattern 31 on the surface of the object 2 subjected to pattern formation.

The above-described applying process and transferring process maybe repeated by multiple times in this sequence to form and arrange the plurality of first mask patterns 31 side by side on the surface of the object 2 subjected to pattern formation (see FIGS. 1H, 1I, and FIG. 3A).

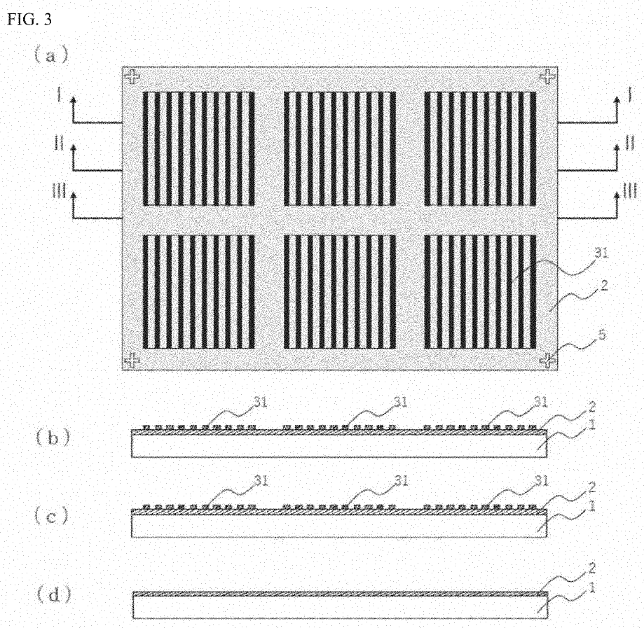

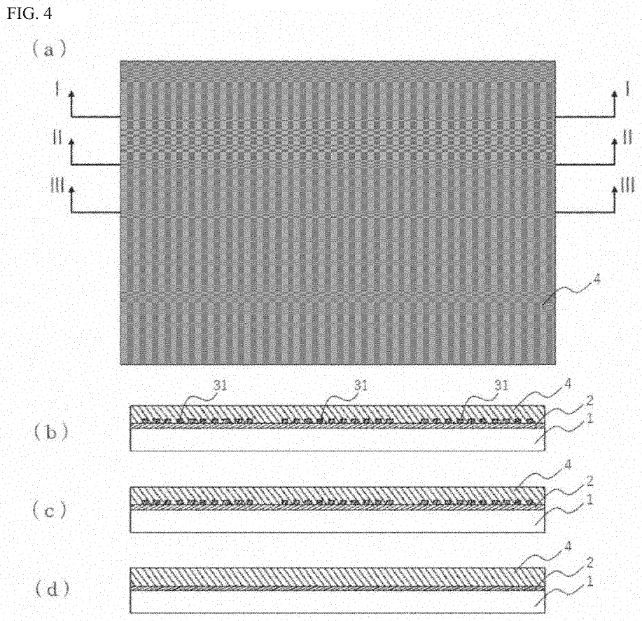

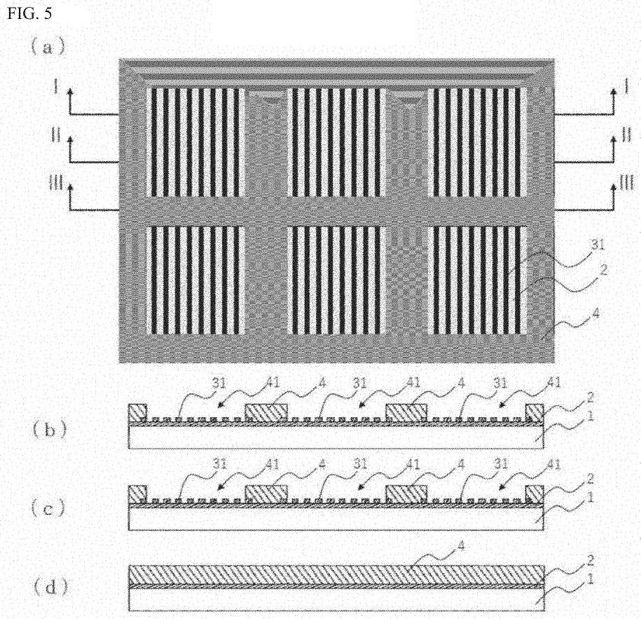

As illustrated in FIGS. 4A to 4D, the second mask pattern forming process is to form the resist film 4 on the object 2 subjected to pattern formation and on the first mask pattern 31, and as illustrated in FIGS. 5A to 5D, to emit light to the resist film 4 so as to be exposed and also developed, thereby forming the second mask pattern 41 in such a way that a region where no micropattern 21 is formed but the first mask pattern 31 is formed appears in an uncovered manner. Hence, the region where no first mask pattern 31 is formed and the region where the micropattern 21 is already formed on the object 2 subjected to pattern formation can be covered with the resist film 4, and other regions are in an uncovered state. Hence, the micropattern 21 can be formed on the region of the object 2 subjected to pattern formation where the micropattern 21 is not formed yet by performing etching in the micropattern forming process to be described later.

Light emission is not limited to any particular type as long as it can form the second mask pattern, but laser lithography which has an excellent alignment precision and which enables the shape of the second mask pattern to be designed freely may be applied. Although any apparatuses may be applied for laser lithography, it is desirable that such an apparatus should have an alignment precision that is equal to or higher than at least the precision required for the micropattern 21. When, for example, the micropattern 21 is the concavo-convex structure in a line-and-space shape for wire grids, as for the laser lithography, it is preferable to have the accuracy that is equal to or higher than the pitch of the line-and-space shape. Note that regarding the light emission, for example, exposure by photolithography, etc., may be applied.

Moreover, the resist applied in the second mask pattern forming process is not limited to any particular one as long as it can form the second mask pattern 41 by lithography and development by laser lithography, and it can protect the object 2 subjected to pattern formation under the resist during etching using the second mask pattern 41. For example, a novolac-based photoresist etc., is applicable.

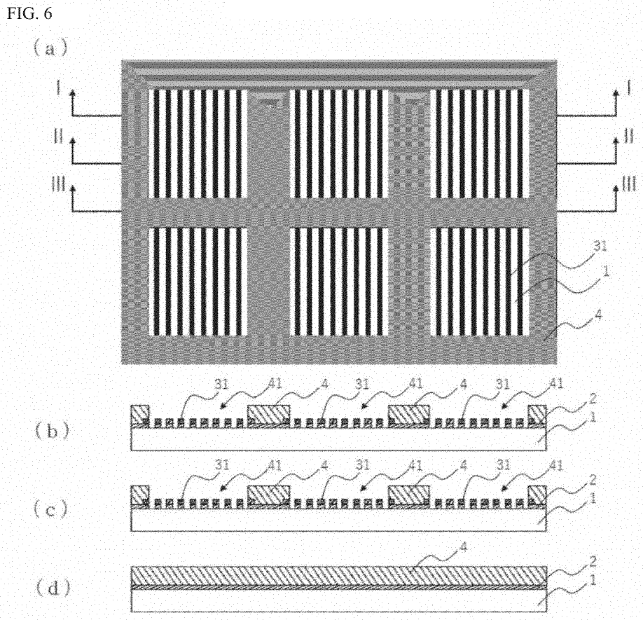

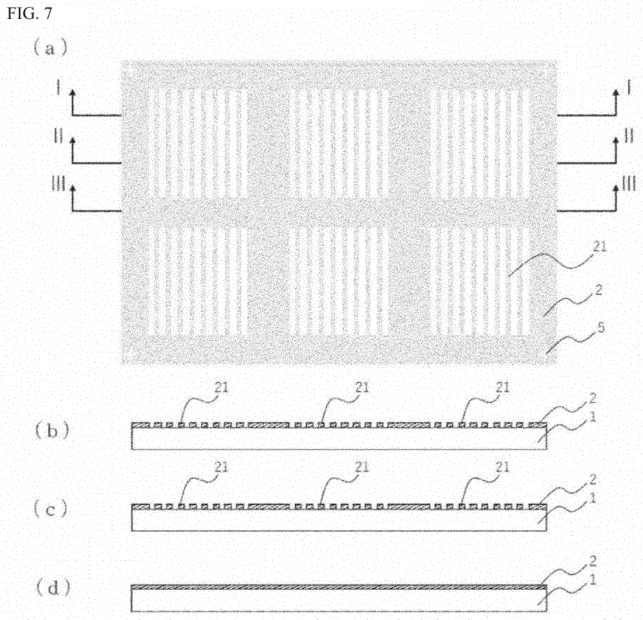

As illustrated in FIGS. 6A to 6D, the micropattern forming process is first to perform etching using the first mask pattern 31 and the second mask pattern 41, and to form the micropattern 21 on the object 2 subjected to pattern formation. Etching is not limited to any particular type as long as it can form the micropattern 21 on the object 2 subjected to pattern formation, but anisotropic etching that can faithfully copy the first mask pattern 31 is desirable. Note that as illustrated in FIGS. 7A to 7D, when there are remaining resin and resist film 4, such resin and resist film 4 are eliminated by asking, etc.

When the first mask pattern forming process, the second mask pattern forming process, and the micropattern forming process as described above are repeated in this sequence and the micropattern 21 is formed on the object 2 subjected to pattern formation, the highly precise micropattern 21 can be formed. Moreover, when the first mask pattern forming process, the second mask pattern forming process, and the micropattern forming process are repeated in this sequence and the micropattern 21 is formed on the object 2 subjected to pattern formation without any space, the highly precise micropattern 21 with a large area can be formed. The space of the micropattern 21 means a space in which the micropattern 21 is not formed and which is between regions where the respective micropatterns 21 are formed in the micropattern forming process.

More specifically, first, as illustrated in FIGS. 3A to 3D, in the first mask pattern forming process at the first time, the first mask pattern 31 is formed by imprinting on the surface of the object 2 subjected to pattern formation in which the micropattern 21 has not been formed yet. Next, in the second mask pattern forming process at the first time, as illustrated in FIGS. 4A to 4D, the resist film 4 is formed on the object 2 subjected to pattern formation and on the first mask pattern 31. Next, exposure and development are performed by light emission, and as illustrated in FIGS. 5A to 5D, the second mask pattern 41 is formed which causes a region where the micropattern 21 is not formed but the first mask pattern 31 is formed to appear in an uncovered manner. Subsequently, as illustrated in FIGS. 6A to 6D, in the micropattern forming process at the first time, etching is performed using the first mask pattern 31 and the second mask pattern 41 to form the micropattern 21 on the object 2 subjected to pattern formation. Subsequently, as illustrated in FIGS. 7A to 7D, the remaining pieces of the first mask pattern 31 and of the resist film 4 are eliminated.

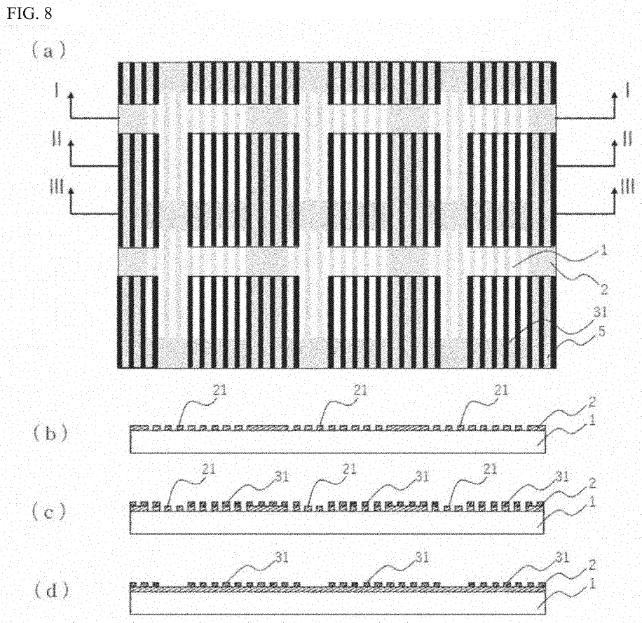

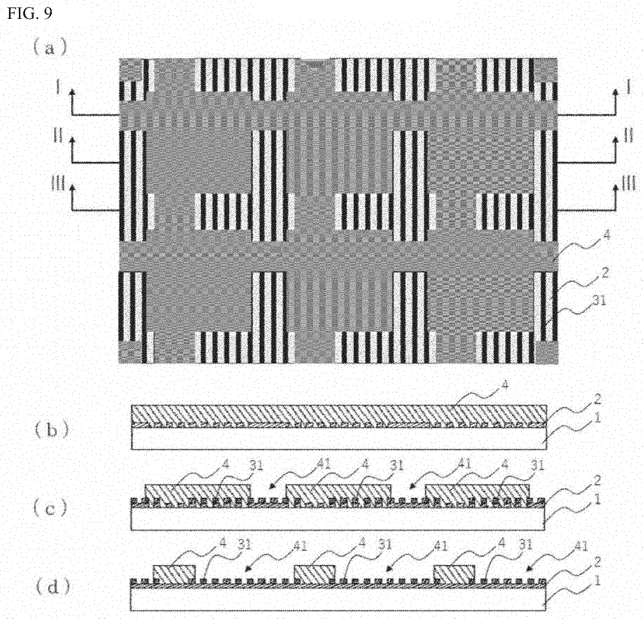

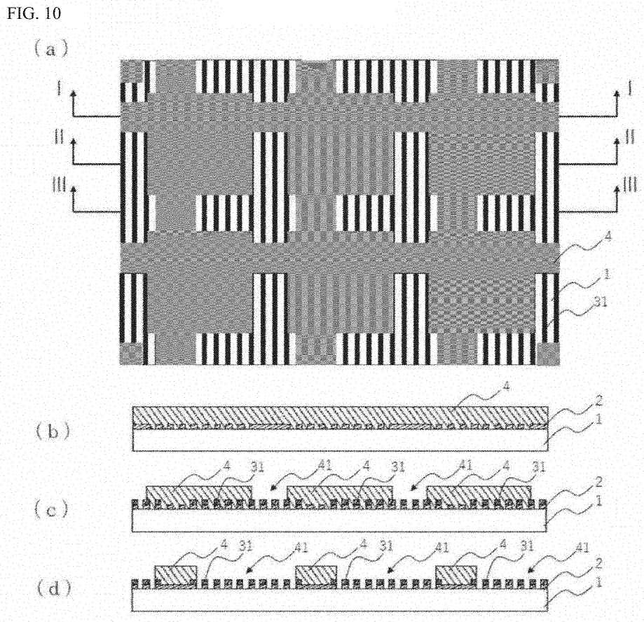

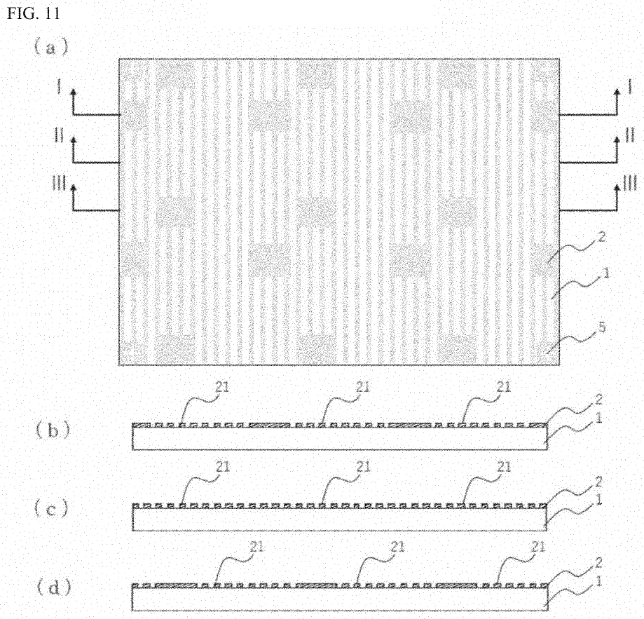

Next, as illustrated in FIGS. 8A to 8D, in the first mask pattern forming process at the second time, the first mask pattern 31 is formed by imprinting on the surface of the object 2 subjected to pattern formation including a region where at least the micropattern 21 is not formed by the first micropattern forming process at the first time. Next, as illustrated in FIGS. 9A to 9D, in the second mask pattern forming process at the second time, the second mask pattern 41 is formed which causes a region where the micropattern 21 is not formed in the first micropattern forming process but the first mask pattern 31 is formed by the first mask pattern forming process at the second time to appear in an uncovered manner. Subsequently, as illustrated in FIGS. 10A to 10D and FIGS. 11A to 11D, the micropattern forming process at the second time is performed to form the micropattern 21 in the space between the micropatterns 21 formed at the first time.

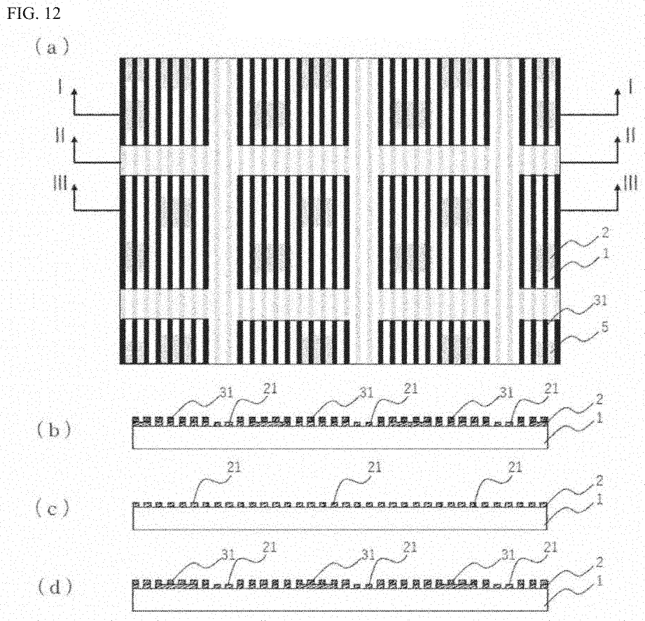

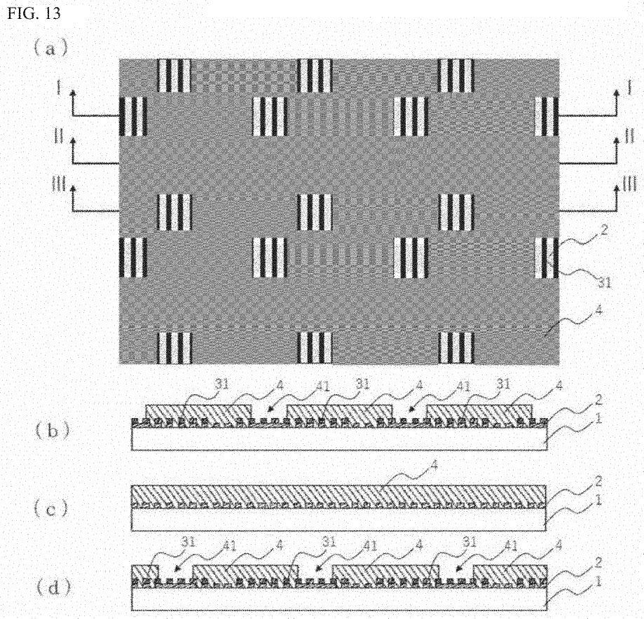

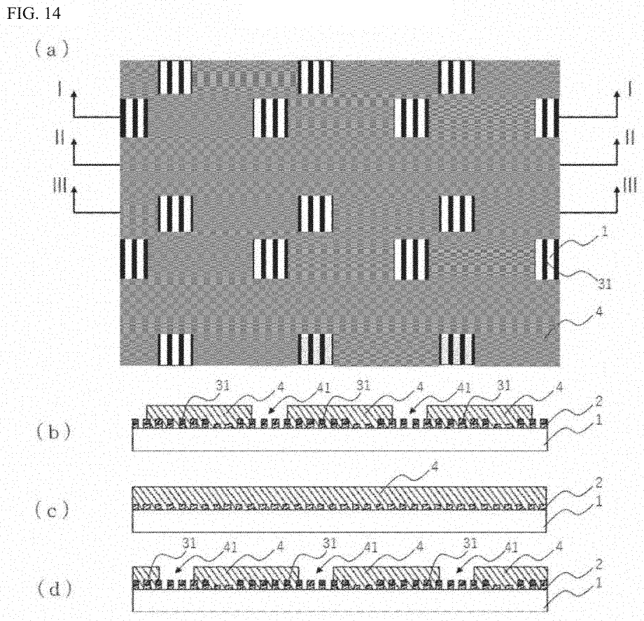

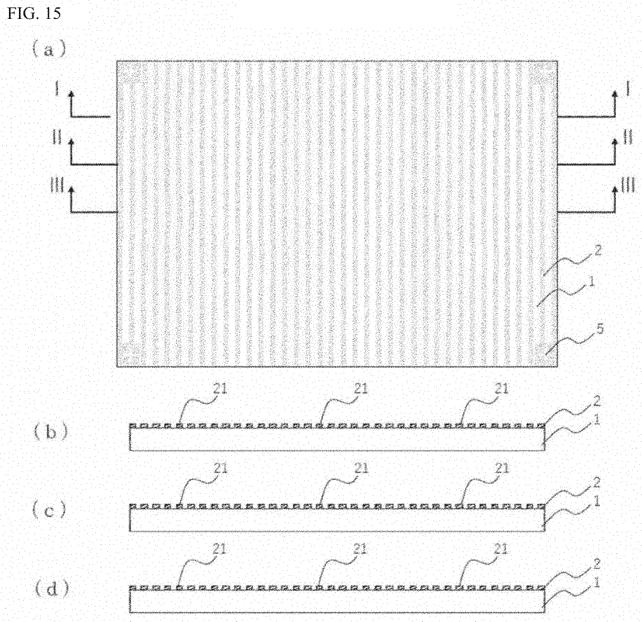

Furthermore, as illustrated in FIGS. 12A to 12D, in the first mask pattern forming process at the third time, the first mask pattern 31 is formed by imprinting on the surface of the object 2 subjected to pattern formation including a region where at least the micropattern 21 is not formed by the first-time and second-time micropattern forming processes. Next, as illustrated in FIGS. 13A to 13D, in the second mask pattern forming process at the third time, the second mask pattern 41 is formed which causes a region where the micropattern 21 is not formed by the first-time and second-time micropattern forming processes but the first mask pattern 31 is formed by the first mask pattern forming process at the third time to appear in an uncovered manner. Next, as illustrated in FIGS. 14A to 14D and FIGS. 15A to 15D, the micropattern forming process at the third time is performed to form the micropattern 21 in the space between the micropatterns 21 formed at the first time and at the second time.

As described above, when the first mask pattern forming process, the second mask pattern forming process, and the micropattern forming process are repeated in this sequence by least three times, as illustrated in FIGS. 15A to 15D, the micropatterns 21 with a large area can be formed on the object 2 subjected to pattern formation without a space.

Note that in the second mask pattern forming process, it is necessary to precisely form the second mask pattern in such a way that the region where the micropattern 21 is not formed but the first mask pattern 31 is formed is caused to appear in an uncovered manner. Hence, it is preferable that light emission in the second mask pattern forming process subsequent to at least the second time should be performed using alignment markings 5 formed on the object subjected to pattern formation.

In this case, although the object 2 subjected to pattern formation on which the alignment markings 5 for light emission are formed in advance may be applied according to the present disclosure, when the alignment marking 5 is not formed, the alignment markings 5 may be formed on the object 2 subjected to pattern formation by an alignment marking forming process. In the alignment marking forming process, the resist film 4 is formed on the object 2 subjected to pattern formation, the resist film 4 is exposed and developed by emission of light like laser to form a mask pattern for the alignment markings, etching is performed using the mask pattern for alignment markings, and thus the alignment markings 5 are formed on the object 2 subjected to pattern formation. The shape of the alignment marking 5 may be a cross shape, a line shape, a rectangular shape, or an L-shape, etc., and is not limited to any particular shape as long as it is applicable to an adopted laser lithography device.

Moreover, although the alignment marking forming process may be executed in advance prior to the first mask pattern forming process at the first time, in order to simplify the processes, may be executed simultaneously with the first mask pattern forming process at the first time. More specifically, in the second mask pattern forming process at the first time, the resist film 4 may be exposed by emission of light like laser, and the mask pattern for alignment markings may be formed simultaneously with the formation of the second mask pattern 41 by development.

Furthermore, a second micropattern 11 can be formed on the substrate 1 with the object 2 subjected to pattern formation and on which the micropatterns 21 are formed as described above being as a hard mask. That is, the micropatterns 11 may be formed on the substrate 1 by a hard surface mask forming process of forming, on the object 2 subjected to pattern formation on the substrate 1, a hard mask that has the first micropatterns 21 formed by the above-described forming method of the present disclosure, and a second micropattern forming process of forming the second micropatterns 11 on the substrate 1 by etching that utilizes the hard mask. Such a forming method may be applicable as an imprinting mold producing method for forming an imprinting mold. The material and shape, etc., of the imprinting mold are the same as those of the mold 36 as described above.

Note that the object 2 subjected to pattern formation for forming the hard mask may be formed on the substrate 1 prior to the first mask pattern forming process at the first time as illustrated in FIGS. 2A to 2D. An appropriate material of the hard mask (the object 2 subjected to pattern formation) may be a material that has a relatively excellent selectivity of etching to the substrate 1. When, for example, the above-described forming method is applied as the imprinting mold producing method for forming the imprinting mold formed of silica glass, a metal like chromium may be applied. Moreover, the object 2 subjected to pattern formation for the hard mask may be formed by plating, or CVD, etc., on the surface of the substrate 1.

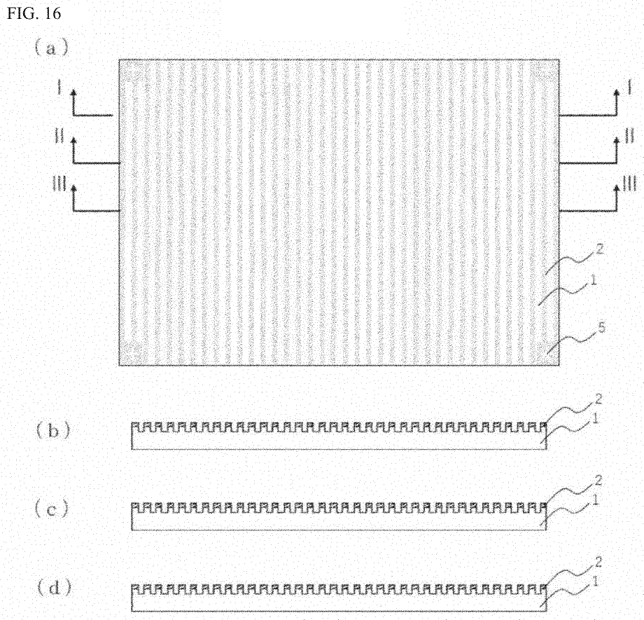

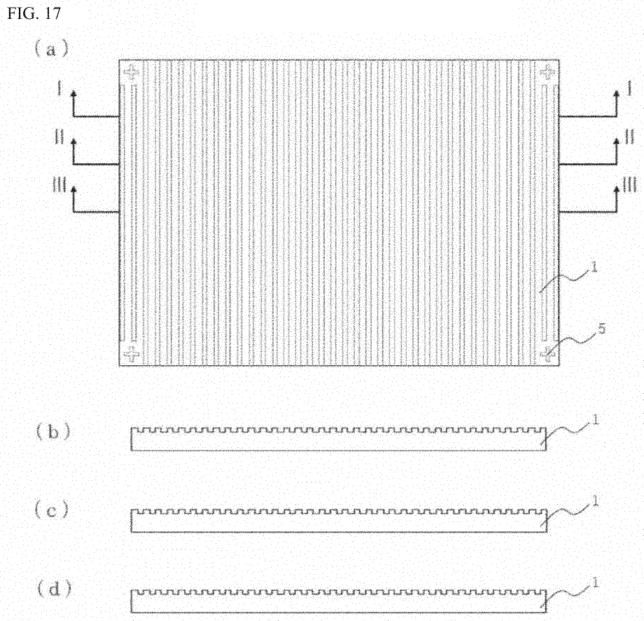

As illustrated in FIGS. 16A to 16D, the second micropattern forming process performs etching using the hard mask, and forms the second micropatterns 11 on the substrate 1. Etching is not limited to any particular type as long as it can form the second micropattern 11 on the substrate 1, but anisotropic etching that can faithfully copy the first micropattern 21 is desirable. Subsequently, as illustrated in FIGS. 17A to 17D, the hard mask may be eliminated.

The object subjected to pattern formation and the substrate which have a large-area micropattern formed as described above can be utilized as a master mold for forming the imprinting mold, and as the imprinting mold formed of resin. In this case, the alignment markings utilized for light emission in the second mask pattern forming process may be directly utilized as alignment markings for such a mold.

Next, a method of producing an optical device that has plural kinds of micropatterns formed on each of a plurality of optical elements 6 already formed on a substrate 1A by the forming method according to the present disclosure will be described. In this example, a case will be described in which a wire grid (micropattern 21A or 21B) that has a different polarization direction by 90 degrees is formed on each of the optical elements 6 like image sensors.

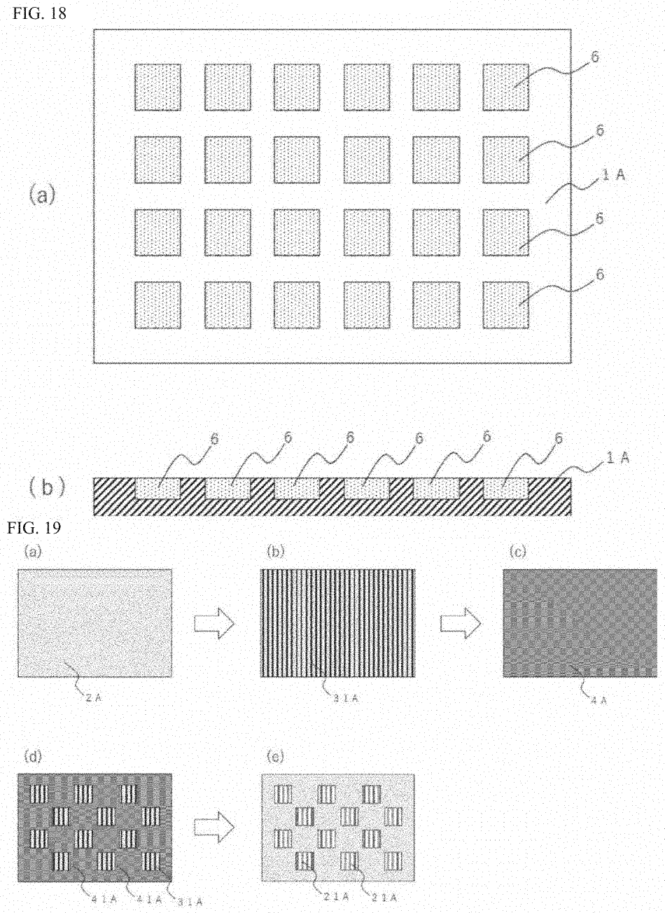

First, as illustrated in FIGS. 18A and 18B, the substrate 1A that has the optical elements 6 like image sensors already formed is prepared. Next, as illustrated in FIG. 19A, the film of the object 2A subjected to pattern formation that is formed of a material which becomes the wire grid is formed on the substrate 1A. The material of the object 2A subjected to pattern formation is not limited to any particular material as long as it can adjust polarization after a pattern as the wire grid is formed, but for example, metal or metal oxides are applicable, such as aluminum (AL), silver (Ag), tungsten (W), amorphous silicon, and titanium oxide (TiO²). Although the film forming method is not limited to any particular method, for example, sputtering is applicable.

Next, as illustrated in FIG. 19B, in the first mask pattern forming process at the first time, a first mask pattern 31A to form the micropattern 21A (the wire grid) is formed by imprinting on the surface of the object 2A subjected to pattern formation. A pattern that is the inverted first mask pattern 31A is utilized as a mold applied in such imprinting.

Next, in the second mask pattern forming process at the first time, as illustrated in FIG. 19C, a resist film 4A is formed on the object 2A subjected to pattern formation and on the first mask pattern 31A. Next, those are exposed and developed by light emission, and as illustrated in FIG. 19D, a second mask pattern 41A is formed in such a way that pieces of the first mask pattern 31A on the predetermined optical elements 6 appear in an uncovered manner.

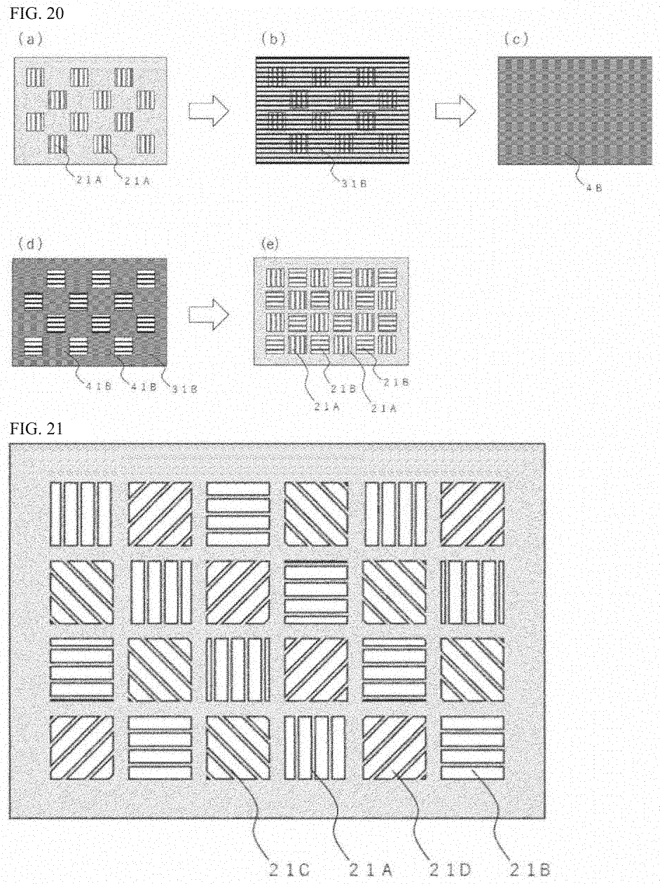

Next, as illustrated in FIG. 19E (also FIG. 20A), in the micropattern forming process at the first time, etching is performed using the first mask pattern 31A and the second mask pattern 41A, and the remaining pieces of the first mask pattern 31A and of the resist film 4A are eliminated, thereby forming the micropattern 21A.

Next, as illustrated in FIG. 20B, in the first mask pattern forming process at the second time, the first mask pattern 31B to form the micropattern 21B (the wire grid) is formed by imprinting on the surface of the object 2A subjected to pattern formation. The first mask pattern 31B is the first mask pattern 31A rotated by 90 degrees. Although the pattern that is the inverted first mask pattern 31B is applied as a mold in such imprinting, the mold applied in the first mask pattern forming process at the first time may be rotated by 90 degrees and applied.

Next, in the second mask pattern forming process at the second time, as illustrated in FIG. 20C, a resist film 4B is formed on the object 2A subjected to pattern formation and on the first mask pattern 31B. Next, those are exposed and developed by light emission, and as illustrated in FIG. 20D, in the second mask pattern forming process at the second time, a second mask pattern 41B is formed in such a way that the pieces of the first mask pattern 31B on the optical elements 6 on which the micropattern 21 is not formed by the micropattern forming process at the first time appear in an uncovered manner.

Eventually, as illustrated in FIG. 20E, in the micropattern forming process at the second time, etching is performed using the first mask pattern 31B and the second mask pattern 41B, and the remaining pieces of the first mask pattern 31B and of the resist film 4B are eliminated, thereby forming the micropattern 21B.

When the first mask pattern forming process and the second mask pattern forming process are repeated as described above, as illustrated in FIG. 20E, the micropattern that has the direction and the position controlled can be formed for each predetermined position on the optical element 6.

Note that in the above-described embodiment, the description has been given of the case in which the first mask pattern forming process, the second mask pattern forming process, and the micropattern forming process are repeated twice in this sequence to form the two kinds of micropatterns 21A and 21B (the wire grids) that have polarization directions different by 90 degrees are respectively formed on the respective optical elements 6 like image sensors. However, the kind of the pattern to be formed is not limited to such kind. For example, as illustrated in FIG. 21, four kinds of micropatterns 21A, 21B, 21C, and 21D (the wire grids) that have polarization directions different by 45 degrees may be formed on the respective optical elements 6 like image sensors. In this case, the first mask pattern forming process, the second mask pattern forming process, and the micropattern forming process may be repeated by four times in this sequence.

### REFERENCE SIGNS LIST

1, 1A Substrate
2, 2A Object subjected to pattern formation
3 Resin film
4, 4A, 4B Resist film
5 Alignment marking
6 Optical element
11 Micropattern
21, 21A, 21B Micropattern
31, 31A, 31B First mask pattern
41, 41A, 41B Second mask pattern

What is claimed is:

1. A forming method of forming a micropattern, the method comprising:
a first mask pattern forming process of forming, by imprinting, a first mask pattern for forming the micropattern on a surface of an object subjected to pattern formation, the surface including a region where at least the micropattern is not formed yet;
a second mask pattern forming process of forming a resist film on the object subjected to pattern formation and on the first mask pattern, exposing and developing the resist film by light emission to form a second mask pattern that causes a region where the micropattern is not formed but the first mask patten is formed to appear in an uncovered manner; and
a micropattern forming process of performing etching using the first mask pattern and the second mask pattern to form the micropattern on the object subjected to pattern formation;
wherein the first mask pattern forming process, the second mask pattern forming process and the micropattern forming process are repeated in this sequence to form the micropattern.

2. The forming method according to claim 1, wherein the light emission in the second mask pattern forming process utilizes laser lithography.

3. The forming method according to claim 1, wherein the first mask pattern forming process, the second mask pattern forming process and the micropattern forming process are repeated by three times.

4. The forming method according to claim 1, wherein the light emission in the second mask pattern forming process subsequent to at least a second time is performed using an alignment marking formed on the object subjected to pattern formation.

5. The forming method according to claim 4, further comprising an alignment marking forming process of forming a resist film on the object subjected to pattern formation, exposing and developing the resist film by light emission to form an alignment marking mask pattern, performing etching using the alignment marking mask pattern, and forming the alignment marking on the object subjected to pattern formation.

6. The forming method according to claim 5, wherein the alignment marking forming process is to expose the resist film formed in the second mask pattern forming process at a first time by light emission, to form the alignment marking mask pattern simultaneously with the formation of the second mask pattern by the development in the second mask pattern forming process at the first time, and to form the alignment marking by the etching in the micropattern forming process at the first time.

7. The forming method according to claim 1, wherein the micropattern has a pitch that is equal to or smaller than 200 nm.

8. The forming method according to claim 1, wherein the imprinting comprises:
an applying process of causing a mold that has an inverted pattern of the first mask pattern to contact a stamp stage on which a film formed of a resin with a film thickness of equal to or smaller than 200 nm is formed to apply the resin on a surface of the mold; and
a transferring process of depressing the mold against the object subjected to pattern formation, releasing the mold after the resin is cured to form the first mask pattern on the surface of the object subjected to pattern formation.

9. A forming method comprising:
a hard mask forming process of forming, on the object subjected to pattern formation and formed on a substrate, a hard mask that includes the first micropattern formed by the forming method according to any one of claims 1 to 8; and
a second micropattern forming process of performing etching using the hard mask to form a second micropattern on the substate.

10. An imprinting mold producing method of forming an imprinting mold by the forming method according to claim 9.

11. An imprinting mold comprising:
a plurality of micropatterns each in a line-and-space shape and coupled to each other; and
alignment markings provided around regions where the respective micropatterns are formed.

12. An optical device comprising:
a plurality of optical elements formed on a substrate; and
plural kinds of wire grids formed on the respective optical elements.
